(19) United States
(12) Patent Application Publication
(10) Pub. No.: US 2020/0003937 A1
(43) Pub. Date: Jan. 2, 2020

(54) USING FLOWABLE CVD TO GAP FILL MICRO/NANO STRUCTURES FOR OPTICAL COMPONENTS

(71) Applicant: Applied Materials, Inc., Santa Clara, CA (US)

(72) Inventors: Jinxin FU, Fremont, CA (US); Ludovic GODET, Sunnyvale, CA (US); Wayne MCMILLAN, San Jose, CA (US)

(21) Appl. No.: 16/120,707

(22) Filed: Sep. 4, 2018

Related U.S. Application Data
(60) Provisional application No. 62/692,255, filed on Jun. 29, 2018.

(51) Int. Cl. G02B 5/18; G03F 7/00; C23C 16/40; C23C 16/56

(52) U.S. Cl. CPC G02B 5/1857; C23C 16/56; C23C 16/402; G03F 7/0007

(57) ABSTRACT

Embodiments of the present disclosure generally relate to a method for forming an optical component, for example, for a virtual reality or augmented reality display device. In one embodiment, the method includes forming a first layer having a pattern on a substrate, and the first layer has a first refractive index. The method further includes forming a second layer on the first layer by a flowable chemical vapor deposition (FCVD) process, and the second layer has a second refractive index less than the first refractive index.

### CROSS-REFERENCE TO RELATED APPLICATIONS

This application claims priority to U.S. Provisional Patent Application Ser. No. 62/692,255, filed on Jun. 29, 2018, which herein is incorporated by reference.

### BACKGROUND

### Field

Embodiments of the present disclosure generally relate to display devices for augmented, virtual, and mixed reality. More specifically, embodiments described herein provide a method for forming an optical component for a display device.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment.

Augmented reality enables an experience in which a user can still see through the display lenses of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences.

Both virtual reality and augmented reality display devices utilize optical components, such as waveguides or flat lens/meta surfaces, including micro or nano structures with contrasting refractive index (RI). Conventionally, a layer having a lower RI is patterned using light, e-beam, or nanoimprint lithography process, and a layer having a higher RI is formed on the patterned lower RI layer using atomic layer deposition (ALD) process. However, the film deposition rate of the ALD process is very slow.

Accordingly, an improved method for forming optical components for virtual reality or augmented reality display devices is needed.

### SUMMARY

Embodiments of the present disclosure generally relate to a method for forming an optical component, for example, for a virtual reality or augmented reality display device. In one embodiment, a method includes forming a first layer having a pattern on a substrate, and the first layer has a first refractive index. The method further includes forming a second layer on the first layer by a flowable chemical vapor deposition process. The second layer has a second refractive index less than the first refractive index.

In another embodiment, a method includes forming a first layer having a pattern on a substrate. The first layer has a first refractive index ranging from about 1.7 to about 2.4. The method further includes forming a second layer on the first layer by a flowable chemical vapor deposition process. The second layer has a second refractive index ranging from about 1.1 to about 1.5.

In another embodiment, a method includes forming a first layer having a first pattern on a substrate. The first layer has a first refractive index and includes a metal oxide. The method further includes forming a second layer on the first layer by a flowable chemical vapor deposition process. The second layer has a second refractive index ranging from about 1.1 to about 1.5.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic cross-sectional view of a processing chamber according to one embodiment described herein.

FIGS. 2A-2D illustrate schematic cross-sectional views of an optical component during different stages according to one embodiment described herein.

FIGS. 3A-3D illustrate schematic cross-sectional views of an optical component according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a method for forming an optical component, for example, for a virtual reality or augmented reality display device. In one embodiment, the method includes forming a first layer having a pattern on a substrate, and the first layer has a first refractive index. The method further includes forming a second layer on the first layer by a flowable chemical vapor deposition (FCVD) process, and the second layer has a second refractive index less than the first refractive index.

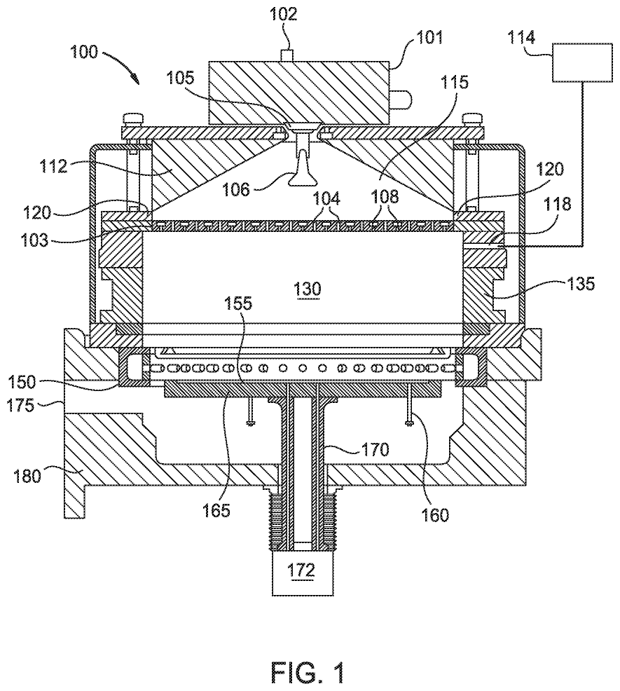

FIG. 1 is a schematic cross-sectional side view of a processing chamber 100 according to one embodiment described herein. The processing chamber 100 may be a deposition chamber, such as a CVD chamber. The processing chamber 100 may be configured at least to deposit a flowable film on a substrate. The processing chamber 100 includes a lid 112 disposed over a chamber wall 135, and an insulating ring 120 disposed between the lid 112 and the chamber wall 135. A first remote plasma source (RPS) 101 is disposed on the lid 112 and precursor radicals formed in the first RPS 101 are flowed into a plasma zone 115 of the processing chamber 100 via a radical inlet assembly 105 and a baffle 106. While the first RPS 101 is illustrated as coupled to the lid 112, it is contemplated that he first RPS 101 may be spaced from the lid 112 and fluidly coupled to the lid 112 by one or more conduits. A precursor gas inlet 102 is formed on the first RPS 101 for flowing one or more precursor gases into the first RPS 101.

The processing chamber 100 further includes a dual-zone showerhead 103. The dual-zone showerhead 103 includes a first plurality of channels 104 and a second plurality of channels 108. The first plurality of channels 104 and the second plurality of channels 108 are not in fluid communication. During operation, radicals in the plasma zone 115 flow into a processing region 130 through the first plurality of channels 104 of the dual-zone showerhead 103, and one or more precursor gases flow into the processing region 130 through the second plurality of channels 108. With the dual-zone showerhead 103, premature mixing and reaction between the radicals and the precursor gases are avoided.

The processing chamber 100 includes a substrate support 165 for supporting a substrate 155 during processing. The processing region 130 is defined by the dual-zone showerhead 103 and the substrate support 165. A second RPS 114 is fluidly coupled to the processing region 130 through the chamber wall 135 of the processing chamber 100. The second RPS 114 may be coupled to an inlet 118 formed in the chamber wall 135. Since the precursor gas and precursor radicals mix and react in the processing region 130 below the dual-zone showerhead 103, deposition primarily occurs below the dual-zone showerhead 103 except some minor back diffusion. Thus, the components of the processing chamber 100 disposed below the dual-zone showerhead 103 may be cleaned after periodic processing. Cleaning refers to removing material deposited on the chamber components. The cleaning radicals are introduced into the processing region 130 at a location below (downstream of) the dual-zone showerhead 103.

The first RPS 101 is configured to excite a precursor gas, such as a silicon containing gas, an oxygen containing gas, and/or a nitrogen containing gas, to form precursor radicals that form a flowable film on the substrate 155 disposed on the substrate support 165. The second RPS 114 is configured to excite a cleaning gas, such as a fluorine containing gas, to form cleaning radicals that clean components of the processing chamber 100, such as the substrate support 165 and the chamber wall 135.

The processing chamber 100 further includes a bottom 180, a slit valve opening 175 formed in the bottom 180, and a pumping ring 150 coupled to the bottom 180. The pumping ring 150 is utilized to remove residual precursor gases and radicals from the processing chamber 100. The processing chamber 100 further includes a plurality of lift pins 160 for raising the substrate 155 from the substrate support 165 and a shaft 170 supporting the substrate support 165. The shaft 170 is coupled to a motor 172 which can rotate the shaft 170, which in turn rotates the substrate support 165 and the substrate 155 disposed on the substrate support 165. Rotating the substrate support 165 during processing or cleaning can achieve improved deposition uniformity as well as clean uniformity.

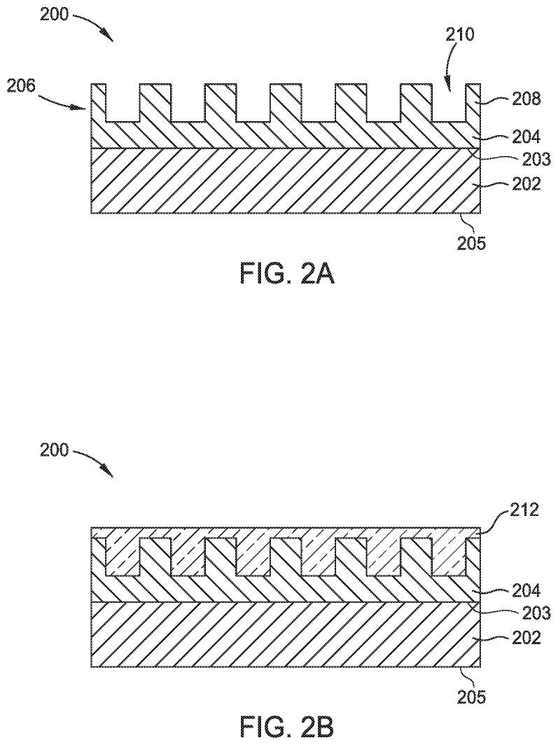

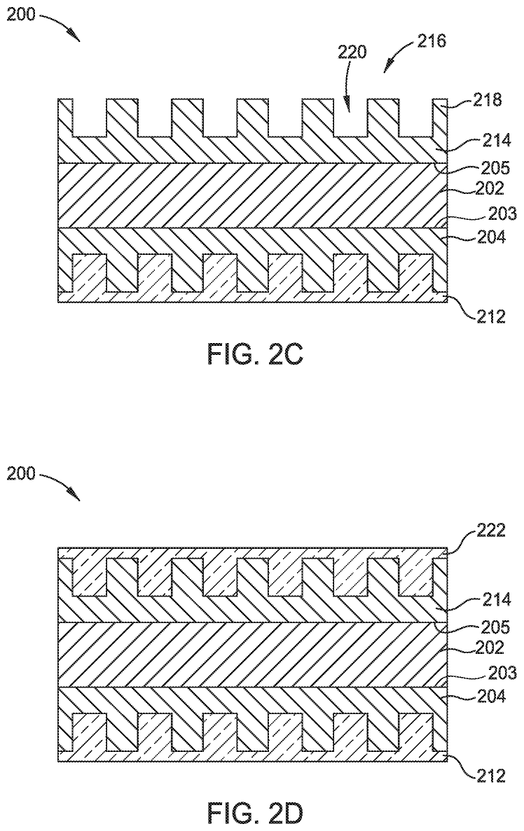

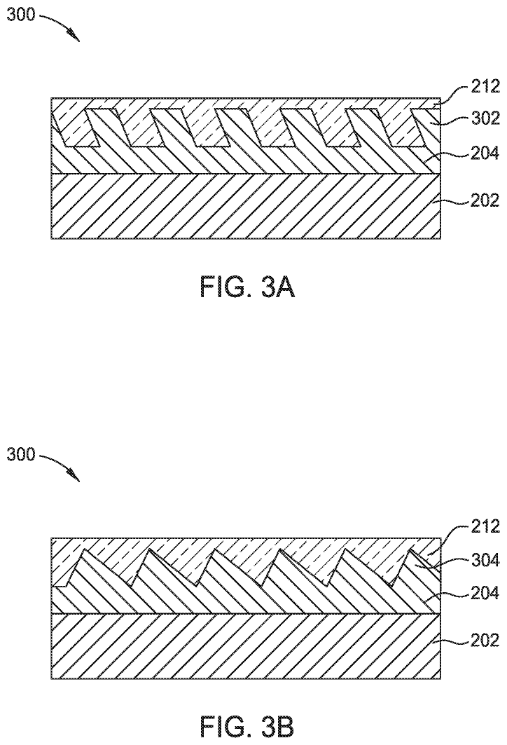

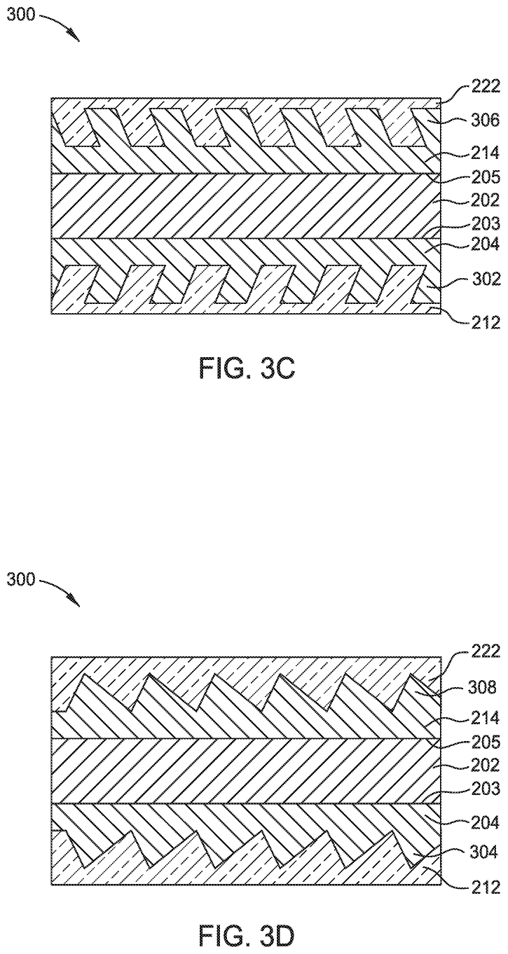

FIGS. 2A-2D illustrate schematic cross-sectional views of an optical component 200 during different stages according to one embodiment described herein. As shown in FIG. 2A, the optical component 200 includes a patterned first layer 204 having a first RI disposed on a first surface 203 of a substrate 202. The substrate 202 may be the substrate 155 shown in FIG. 1. In one embodiment, the substrate 202 is fabricated from a visually transparent material, such as glass. The substrate 202 has a RI ranging from about 1.4 to about 2.0. The patterned first layer 204 is fabricated from a transparent material, and the first RI ranges from about 1.7 to about 2.4. In one embodiment, the RI of the substrate 202 is the same as the first RI of the patterned first layer 204. In another embodiment, the RI of the substrate 202 is different from the first RI of the patterned first layer 204. The patterned first layer 204 is fabricated from a metal oxide, such as titanium oxide (TiOₓ), tantalum oxide (TaOₓ), zirconium oxide (ZrOₓ), hafnium oxide (HfOₓ), or niobium oxide (NbOₓ). The patterned first layer 204 includes a pattern 206, and the pattern 206 includes a plurality of protrusions 208 and a plurality of gaps 210. Adjacent protrusions 208 are separated by a gap 210. As shown in FIG. 2A, the protrusion 208 has a rectangular shape. The protrusion 208 may have any other suitable shape. Examples of the protrusion 208 having different shapes are shown in FIGS. 3A-3D. In one embodiment, the protrusions 208 are gratings. Gratings are a plurality of parallel elongated structures that splits and diffracts light into several beams traveling in different directions. Gratings may have different shapes, such as sine, square, triangle, or sawtooth gratings. The patterned first layer 204 may be formed by any suitable method, such as e-beam lithography, nanoimprint lithography, or etching.

Next, the substrate 202 and the patterned first layer 204 formed thereon are placed into a processing chamber, such as the processing chamber 100 shown in FIG. 1. A second layer 212 is formed on the patterned first layer 204 by an FCVD process. The flowable nature of the second layer 212 allows the second layer 212 to flow into small gaps, such as gaps 210. The second layer 212 has a second RI that is less than the first RI. In one embodiment, the layer 212 has a RI ranging from about 1.1 to about 1.5.

The second layer may be formed by the following process steps. An atomic oxygen precursor is generated in an RPS, such as the first RPS 101 of the processing chamber 100. The atomic oxygen may be generated by the dissociation of an oxygen containing precursor such as molecular oxygen (O₂), ozone (O₃), an nitrogen-oxygen compound (e.g., NO, NO₂, N₂O, etc.), a hydrogen-oxygen compound (e.g., H₂O, H₂O₂, etc.), a carbon-oxygen compound (e.g., CO, CO₂, etc.), as well as other oxygen containing precursors and combinations of precursors. The reactive atomic oxygen is then introduced to a processing region, such as the processing region 130 of the processing chamber 100 shown in FIG. 1, where the atomic oxygen may mix for the first time with a silicon precursor, which is also introduced to the processing region. The atomic oxygen reacts with the silicon precursor (and other deposition precursors that may be present in the reaction chamber) at moderate temperatures (e.g., reaction temperatures less than 100° C.) and pressures (e.g., about 0.1 Torr to about 10 Torr; 0.5 to 6 Torr total chamber pressure, etc.) to form the second layer 212, such as a silicon dioxide layer. In one embodiment, the second layer 212 is a quartz layer.

The silicon precursor may include an organosilane compound and/or silicon compound that does not contain carbon. Silicon precursors without carbon may include silane (SiH₄), among others. Organosilane compounds may include compounds with direct Si—C bonding and/or compounds with Si—O—C bonding. Examples of organosilane silicon precursors may include dimethylsilane, trimethylsilane, tetramethylsilane, diethylsilane, tetramethylorthosilicate (TMOS), tetraethylorthosilicate (TEOS), octamethyltrisiloxane (OMTS), octamethylcyclotetrasiloxane (OMCTS), tetramethyldimethyldimethoxydisilane, tetramethylcyclotetrasiloxane (TOMCATS), DMDMOS, DEMS, methyl triethoxysilane (MTES), phenyldimethylsilane, and phenylsilane, among others.

The atomic oxygen and silicon precursors are not mixed before being introduced to the processing region. The precursors may enter the processing region through a dual-zone showerhead, such as the dual-zone showerhead 103 shown in FIG. 1. As the atomic oxygen and silicon precursors react in the processing region, the second layer 212 is formed on the patterned first layer 204. The second layer 212 as deposited has excellent flowability, and can quickly migrate into gaps, such as gaps 210.

A post deposition anneal of the second layer 212 may be performed. In one embodiment, the second layer 212 is heated to about 300° C. to about 1000° C. (e.g., about 600° C. to about 900° C.) in a substantially dry atmosphere (e.g., dry nitrogen, helium, argon, etc.). The anneal removes moisture from the deposited second layer 212.

In some embodiments, both sides of the substrate 202 can be utilized to form layers having different RIs thereon. As shown in FIG. 2C, a patterned third layer 214 having a third RI is formed on a second surface 205 of the substrate 202. The patterned third layer 214 has a pattern 216, and the pattern 216 includes a plurality of protrusions 218 and a plurality of gaps 220. The patterned third layer 214 may be fabricated from the same materials as the patterned first layer 204. The patterned third layer 214 may be formed by the same process as the patterned first layer 204. In one embodiment, the patterned third layer 214 is identical to the patterned first layer 204. In another embodiment, the patterned third layer 214 has a different pattern than the patterned first layer 204.

Next, as shown in FIG. 2D, a fourth layer 222 is formed on the patterned third layer 214. The fourth layer 222 may be fabricated from the same materials as the second layer 212. The fourth layer 222 may be formed by the same process as the second layer 212. The optical component 200 may be used in any suitable display devices. For example, in one embodiment, the optical component 200 is used as a waveguide or waveguide combiner in augmented reality display devices. Waveguides are structures that guide optical waves. Waveguide combiners are used in augmented reality display devices that combine real world images with virtual images. In another embodiment, the optical component 200 is used as a flat lens/meta surfaces in augmented and virtual reality display devices and 3D sensing devices, such as face ID and LIDAR.

FIGS. 3A-3D illustrate schematic cross-sectional views of an optical component 300 according to embodiments described herein. As shown in FIG. 3A, the optical component 300 includes the substrate 202, the patterned first layer 204 disposed on the substrate 202, and the second layer 212 disposed on the patterned first layer 204. The patterned first layer 204 includes a plurality of protrusions 302. Each of the protrusions 302 has a parallelogramical cross-sectional area, as shown in FIG. 3A. The protrusions 302 may be gratings.

As shown in FIG. 3B, the optical component 300 includes the substrate 202, the patterned first layer 204 disposed on the substrate 202, and the second layer 212 disposed on the patterned first layer 204. The patterned first layer 204 includes a plurality of protrusions 304. Each of the protrusions 304 has a triangular cross-sectional area, as shown in FIG. 3B. The protrusions 304 may be gratings.

As shown in FIG. 3C, the optical component 300 includes the substrate 202, the patterned first layer 204 disposed on the first surface 203 of the substrate 202, and the second layer 212 disposed on the patterned first layer 204. The patterned first layer 204 includes the plurality of protrusions 302. The optical component 300 further includes the patterned third layer 214 disposed on the second surface 205 of the substrate 202 and the fourth layer 222 disposed on the patterned third layer 214. The patterned third layer 214 includes a plurality of protrusions 306. In one embodiment, the protrusions 306 may be the same as the protrusions 302. In another embodiment, the protrusions 306 may not be the same as the protrusions 302. The protrusions 302, 306 may be gratings.

As shown in FIG. 3D, the optical component 300 includes the substrate 202, the patterned first layer 204 disposed on the first surface 203 of the substrate 202, and the second layer 212 disposed on the patterned first layer 204. The patterned first layer 204 includes the plurality of protrusions 304. The optical component 300 further includes the patterned third layer 214 disposed on the second surface 205 of the substrate 202 and the fourth layer 222 disposed on the patterned third layer 214. The patterned third layer 214 includes a plurality of protrusions 308. In one embodiment, the protrusions 308 may be the same as the protrusions 304. In another embodiment, the protrusions 308 may not be the same as the protrusions 304. The protrusions 304, 308 may be gratings.

The optical component 300 may be used in any suitable display devices. For example, in one embodiment, the optical component 300 is used as a waveguide or waveguide combiner in augmented reality display devices. In another embodiment, the optical component 300 is used as a flat lens/meta surfaces in augmented and virtual reality display devices and 3D sensing devices, such as face ID and LIDAR.

A method for forming an optical component including layers having different RIs is disclosed. A patterned first layer having a higher RI is formed on a substrate, and a second layer is formed on the patterned first layer using FCVD process. The application of the optical component is not limited to augmented and virtual reality display devices and 3D sensing devices. The optical component can be used in any suitable applications.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
forming a first layer having a pattern on a substrate, the first layer having a first refractive index; and
forming a second layer on the first layer by a flowable chemical vapor deposition process, the second layer having a second refractive index less than the first refractive index.

2. The method of claim 1, wherein the first refractive index ranges from about 1.7 to about 2.4.

3. The method of claim 1, wherein the first layer comprises a metal oxide.

4. The method of claim 1, wherein the first layer comprises titanium oxide, tantalum oxide, zirconium oxide, hafnium oxide, or niobium oxide.

5. The method of claim 1, wherein the second layer comprises porous silicon dioxide or quartz.

6. The method of claim 1, wherein the second refractive index ranges from about 1.1 to about 1.5.

7. A method, comprising:
forming a first layer having a pattern on a substrate, the first layer having a first refractive index ranging from about 1.7 to about 2.4; and
forming a second layer on the first layer by a flowable chemical vapor deposition process, the second layer having a second refractive index ranging from about 1.1 to about 1.5.

8. The method of claim 7, wherein the second layer comprises porous silicon dioxide or quartz.

9. The method of claim 7, wherein the first layer comprises a metal oxide.

10. The method of claim 7, wherein the first layer comprises titanium oxide, tantalum oxide, zirconium oxide, hafnium oxide, or niobium oxide.

11. The method of claim 7, further comprising annealing the second layer.

12. The method of claim 11, wherein the annealing the second layer comprises heating the second layer to about 300° C. to about 1000° C.

13. A method, comprising:
forming a first layer having a first pattern on a first surface of a substrate, the first layer having a first refractive index and comprising a metal oxide; and
forming a second layer on the first layer by a flowable chemical vapor deposition process, the second layer having a second refractive index ranging from about 1.1 to about 1.5.

14. The method of claim 13, wherein the first refractive index ranges from about 1.7 to about 2.4.

15. The method of claim 13, wherein the second layer comprises porous silicon dioxide or quartz.

16. The method of claim 13, wherein the first layer comprises titanium oxide, tantalum oxide, zirconium oxide, hafnium oxide, or niobium oxide.

17. The method of claim 13, wherein the first layer is formed on the first surface of the substrate by e-beam lithography or nanoimprint lithography.

18. The method of claim 13, further comprising forming a third layer having a third refractive index on a second surface of the substrate, the third layer having a second pattern.

19. The method of claim 18, further comprising:
forming a fourth layer having a fourth refractive index less than the third refractive index on the third layer by the flowable chemical vapor deposition process.

20. The method of claim 19, wherein the second pattern is different from the first pattern.
